(19) United States
(12) Patent Application Publication
(10) Pub. No.: US 2007/0019760 A1
(43) Pub. Date: Jan. 25, 2007

(54) System and method for operating a phase-locked loop

(75) Inventors: James Maligeorgos, Austin, TX (US); G. Diwakar Vishakhadatta, Austin, TX (US)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(73) Assignee: Silicon Laboratories, Inc.

(21) Appl. No.: 11/186,501

(22) Filed: Jul. 21, 2005

(51) Int. Cl. H03D 3/24

(52) U.S. Cl. 375/327

(57) ABSTRACT

A mobile communications system comprising a phase-locked loop (PLL), radio frequency (RF) circuitry, and control circuitry configured to activate the PLL and the RF circuitry during a plurality of substantially mutually exclusive time intervals is provided.

### CROSS-REFERENCE TO RELATED APPLICATION

This application relates to U.S. patent application Ser. No. 10/426,042 entitled “Highly Integrated Radio-Frequency Apparatus and Associated Methods”, filed on Apr. 29, 2003, and listing Navdeep S. Sooch and G. Tyson Tuttle as inventors. The above U.S. Patent Application is assigned to the assignee of the present invention and is hereby incorporated by reference herein.

### BACKGROUND

In various types of electrical circuits, electromagnetic interference may cause problems with the operation of the circuits. The interference may increase when circuit elements are spaced in close proximity to one another, e.g., by integrating the circuit elements on the same circuit. With closely spaced circuit elements, the operation of certain circuit elements may interfere with the operation of other circuit elements. Although interference may be reduced by increasing the spacing between circuit elements or electrically isolating circuit elements, the size of the overall circuit may be increased.

It would be desirable to be able to minimize interference between circuit elements without increasing the size of the overall circuit.

### SUMMARY

According to one exemplary embodiment, a mobile communications system comprising a phase-locked loop (PLL), radio frequency (RF) circuitry, and control circuitry configured to activate the PLL and the RF circuitry during a plurality of substantially mutually exclusive time intervals is provided.

According to another exemplary embodiment, a method performed by a system that includes radio frequency (RF) circuitry is provided. The method comprises activating the RF circuitry during a first time interval and deactivating a phase-locked loop (PLL), associated with digital circuitry, during the first time interval.

According to a further exemplary embodiment, a communications device comprising an antenna, a mobile communications system including radio frequency (RF) circuitry and a phase-locked loop (PLL) and configured to communicate with a remote host using the antenna, and an input/output system configured to communicate with the mobile communications system is provided. The mobile communications system is configured to activate the RF circuitry during a first time interval, and the mobile communications system is configured to deactivate the PLL during the first time interval. system comprising:

According to another exemplary embodiment, a system comprising means for activating radio frequency (RF) circuitry during a first time interval and means for deactivating a phase-locked loop (PLL) associated with digital circuitry during the first time interval is provided.

### BRIEF DESCRIPTION OF THE DRAWINGS

FIG. 1 is a block diagram illustrating one embodiment of a mobile communication system.

FIG. 2 is a block diagram one embodiment of a phase-locked loop.

FIG. 3 is a graph illustrating one embodiment of a set of events in a mobile communication system.

FIG. 4 is a graph illustrating one embodiment of operating a mobile communication system.

FIG. 5 is a block diagram illustrating one embodiment of a mobile device that includes the mobile communication system shown in FIG. 1.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

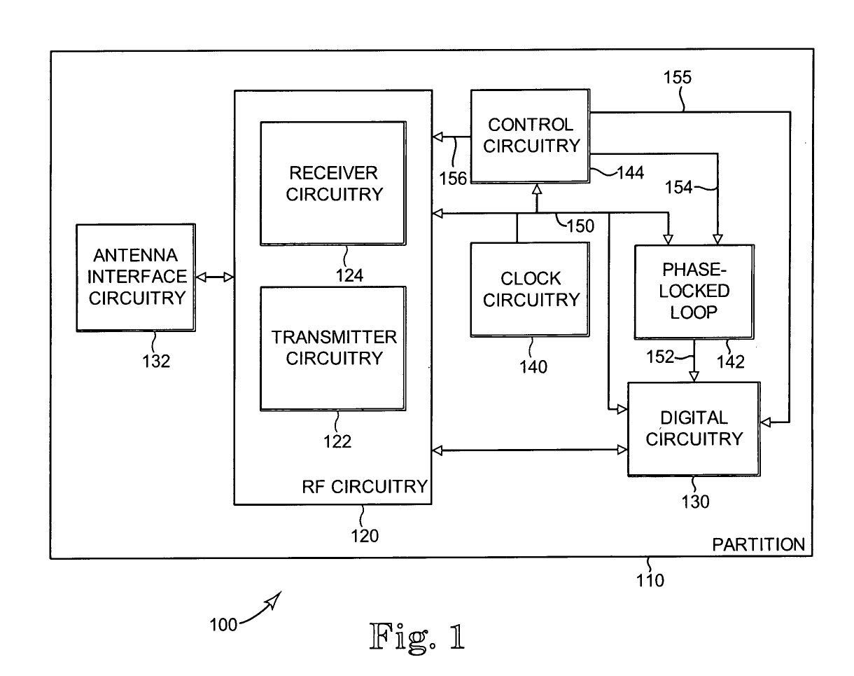

As described herein, a mobile communication system that includes communication circuitry, such as radio-frequency (RF) circuitry, and digital baseband circuitry on a common circuit partition is provided as shown in the embodiments of FIGS. 1-5. The mobile communication system implements time-division isolation to operate the communication circuitry and the digital baseband circuitry during mutually exclusive, or at least substantially mutually exclusive, time intervals so that electrical interference effects between the communication circuitry and the digital baseband circuitry tend to be reduced. Accordingly, the mobile communication system is configured to activate a phase-locked loop to provide a digital circuitry clock signal to the digital baseband circuitry during time intervals when the communication circuitry is inactive. The mobile communication system is also configured to deactivate the phase-locked loop during time intervals when the communication circuitry is active such that the digital circuitry clock signal is not provided to the digital baseband circuitry. Using time-division isolation, the mobile communication system may minimize electrical interference between the communication circuitry and the digital baseband circuitry.

FIG. 1 is a block diagram illustrating one embodiment of a mobile communications system 100. System 100 includes a circuit partition 110. Partition 110 comprises any suitable substrate, carrier, packaging arrangement, or combination thereof. For example, partition 110 may comprise an integrated circuit (IC), a semiconductor die, thin-film substrate, thick-film substrate, an isolated partition on a single substrate, a circuit-board partition, a circuitry, or a multi-chip circuitry. In one embodiment, partition 110 includes radio-frequency (RF) circuitry 120, digital circuitry 130, antenna interface circuitry 132, clock circuitry 140, a phase-locked loop (PLL) 142, and control circuitry 144. In other embodiments, partition 110 includes any suitable combination of less than all of radio-frequency (RF) circuitry 120, digital circuitry 130, antenna interface circuitry 132, clock circuitry 140, PLL 142, and control circuitry 144.

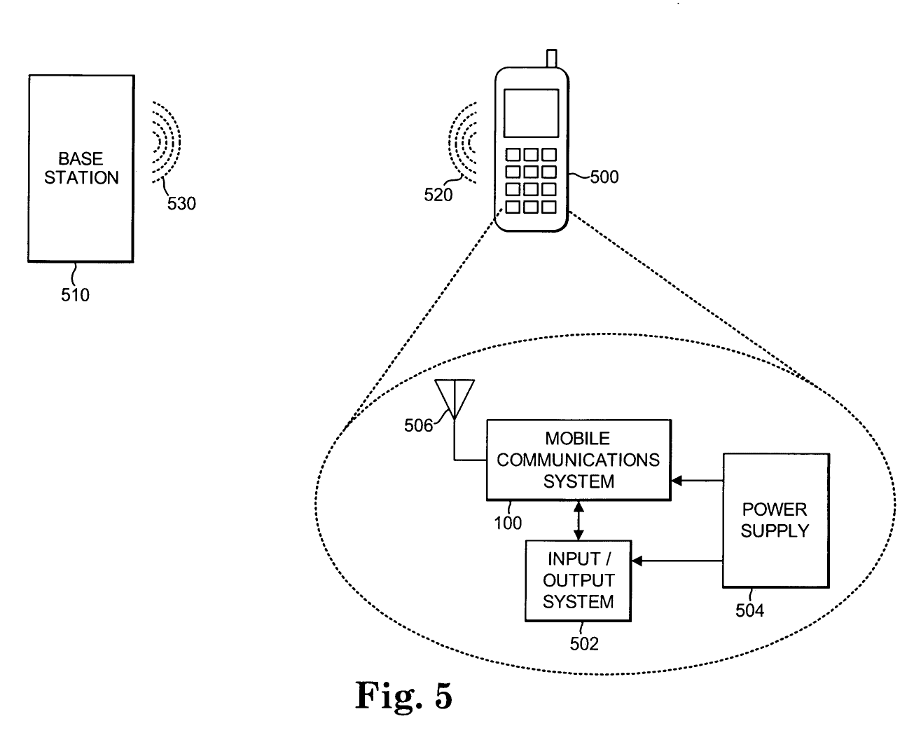

RF circuitry 120 includes transmitter circuitry 122 and receiver circuitry 124. RF circuitry 120 is configured to transmit and receive information using an antenna (e.g., antenna 506 as shown in FIG. 5) coupled, directly or indirectly, to antenna interface circuitry 132. The information may comprise voice or data communications, for example. To transmit information, transmitter circuitry 122 receives information to be transmitted from digital circuitry 130, generates an RF signal that includes the information, and provides the information to antenna interface circuitry 132 for transmission by the antenna. To receive information, receiver circuitry 124 receives an RF signal that includes information from a remote transmitter (e.g., base station 510 as shown in FIG. 5) through the antenna and antenna interface circuitry 132 and provides the information to digital circuitry 130 for processing.

Digital circuitry 130 is configured to perform digital baseband processing on information to be transmitted by RF circuitry 120 and on information received by RF circuitry 120. Digital circuitry 130 may also be configured to perform digital processing on other information that is not associated with RF circuitry 120, i.e., information that is not to be transmitted by or has not been received from RF circuitry 120.

Clock circuitry 140 is configured to generate a reference clock signal 150 and provide reference clock signal 150 to RF circuitry 120, digital circuitry 130, control circuitry 144, and PLL 142. Clock signal 150 drives the operation of RF circuitry 120, control circuitry 144, PLL 142, and at least a portion of digital circuitry 130 in one embodiment. In one embodiment, reference clock signal 150 has a frequency of 26 MHz. In other embodiments, reference clock signal 150 has other suitable frequencies.

PLL 142 is configured to generate a digital circuitry clock signal 152 in response to reference clock signal 150 from clock circuitry 140. PLL 142 provides digital circuitry clock signal 152 to digital circuitry 130 to drive the operation of digital circuitry 130. In one embodiment, digital circuitry clock signal 152 has a frequency of 156 MHz. In other embodiments, digital circuitry clock signal 152 has other suitable frequencies. In operation, PLL 142 may generate electrical interference that causes undesirable effects on the operation of RF circuitry 120. Accordingly, PLL 142 may be activated during time intervals when RF circuitry 120 is deactivated, and PLL 142 may be deactivated during time intervals when RF circuitry 120 is activated as described in additional detail below.

Control circuitry 144 is configured to control the operation of the components of partition 110 including RF circuitry 120, digital circuitry 130, and PLL 142. Control circuitry 144 includes any suitable combination of hardware and/or software components to perform the functions described herein. Control circuitry 144 provides an enable signal 154 to PLL 142 to activate and deactivate PLL 142, and control circuitry 144 provides an enable signal 155 to digital circuitry 130 to activate and deactivate digital circuitry 130. Control circuitry 144 provides an enable signal 156 to RF circuitry 120 to activate and deactivate RF circuitry 120.

To prevent electrical interference between RF circuitry 120 and PLL 142, control circuitry 144 implements time-division isolation between RF circuitry 120 and PLL 142 using enable signals 154, 155, and 156 in one embodiment. With time-division isolation, control circuitry 144 activates RF circuitry 120 and PLL 142 to operate during mutually exclusive, or substantially mutually exclusive, time intervals such as time-slots so that electrical interference effects between RF circuitry 120 and PLL 142 tend to be reduced. With a substantially mutually exclusive time interval, RF circuitry 120 and PLL 142 may both be active during a portion of the time interval. Because PLL 142 provides digital circuitry clock signal 152 to drive digital circuitry 130, control circuitry 144 also causes digital circuitry 130 to be activated and deactivated by activating and deactivating PLL 142, respectively, using enable signals 154 and 155. Accordingly, control circuitry 144 also causes digital circuitry 130 and RF circuitry 120 to operate during mutually exclusive, or substantially mutually exclusive, time intervals so that electrical interference effects between digital circuitry 130 and RF circuitry 120 tend to be reduced.

In a time interval when control circuitry 144 causes RF circuitry 120 to be deactivated using enable signal 156, control circuitry 144 causes PLL 142 to be activated using enable signal 154. Subsequent to activating PLL 142, control circuitry 144 also activates digital circuitry 130 using enable signal 155 to allow digital circuitry 130 to perform operations during the time interval. In a time interval when control circuitry 144 causes RF circuitry 120 to be activated using enable signal 156 to allow RF circuitry 120 to perform operations, control circuitry 144 causes PLL 142 to be deactivated using enable signal 154. Prior to deactivating PLL 142, control circuitry 144 deactivates digital circuitry 130 using enable signal 155 to allow the state of digital circuitry 130 to be maintained.

To deactivate RF circuitry 120, control circuitry 144 causes RF circuitry 120 to partially or fully power down or become partially or fully disabled or inhibited to reduce any electrical interference with PLL 142 to an acceptable level. Similarly, to deactivate PLL 142, control circuitry 144 causes PLL 142 to partially or fully power down or become partially or fully disabled or inhibited to reduce any electrical interference with RF circuitry 120 to an acceptable level.

During a time interval when PLL 142 is deactivated, digital circuitry 130 may perform operations using reference clock signal 150 during a portion of the time interval when RF circuitry 130 is activated as long as the electrical interference with RF circuitry 120 remains below or tends to remain below an acceptable threshold level.

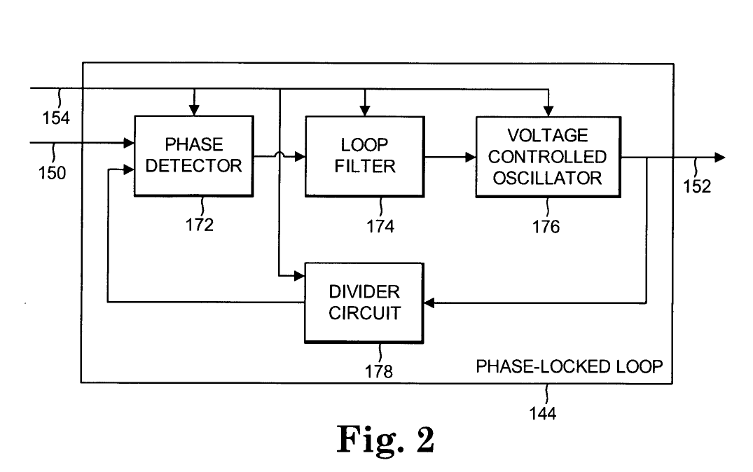

FIG. 2 is a block diagram one embodiment of PLL 142. In the embodiment shown in FIG. 2, PLL 142 includes a phase detector 172, a loop filter 174, a voltage controller oscillator (VCO) 176, and a divider circuit 178.

In the embodiment of FIG. 2, phase detector 172, loop filter 174, voltage controller oscillator (VCO) 176, and divider circuit 178 are each configured to receive enable signal 154 from control circuitry 144. Control circuitry 144 activates and deactivates phase detector 172, loop filter 174, voltage controller oscillator (VCO) 176, and divider circuit 178 using enable signal 154.

In response to being activated by control circuitry 144 using enable signal 154, phase detector 172 receives reference clock signal 150 from clock circuitry 140 as shown in FIG. 1 and a feedback signal from divider circuit 178. Phase detector 172 detects a phase difference between reference clock signal 150 and the feedback signal, generates a phase error signal associated with the phase difference, and provides the phase error signal to loop filter 174. Loop filter 174 receives and filters the phase error signal to generate a filtered phase error signal. Loop filter 174 provides the filtered phase error signal to VCO 176. VCO 176 generates digital circuitry clock signal 152 at a higher frequency than reference clock signal 150 and synchronizes digital circuitry clock signal 152 with reference clock signal 150 using the filtered phase error signal. VCO 176 provides digital circuitry clock signal 152 to divider circuit 178. Divider circuit 178 generates the feedback signal by dividing down digital circuitry clock signal 152 to the frequency of reference clock signal 150 and provides the feedback signal to phase detector 172.

In response to being deactivated by control circuitry 144 using enable signal 154, phase detector 172, loop filter 174, voltage controller oscillator (VCO) 176, and divider circuit 178 cease operating and do not generate digital circuitry clock signal 152.

In other embodiments, control circuitry 144 may provide enable signal 154 to less than all of phase detector 172, loop filter 174, voltage controller oscillator (VCO) 176, and divider circuit 178 to activate and deactivate PLL 142.

In another embodiment not shown, control circuitry 144 prevents reference clock signal 150 from being provided to phase detector 172 using enable signal 154 to activate and deactivate PLL 142.

In other embodiments, clock circuitry 140 may be located externally from partition 110 or within other components within partition 110.

In other embodiments, PLL 142 may be replaced with other frequency synthesizing circuitry configured to generate digital circuitry clock signal 152 and provide digital circuitry clock signal 152 to digital circuitry 130.

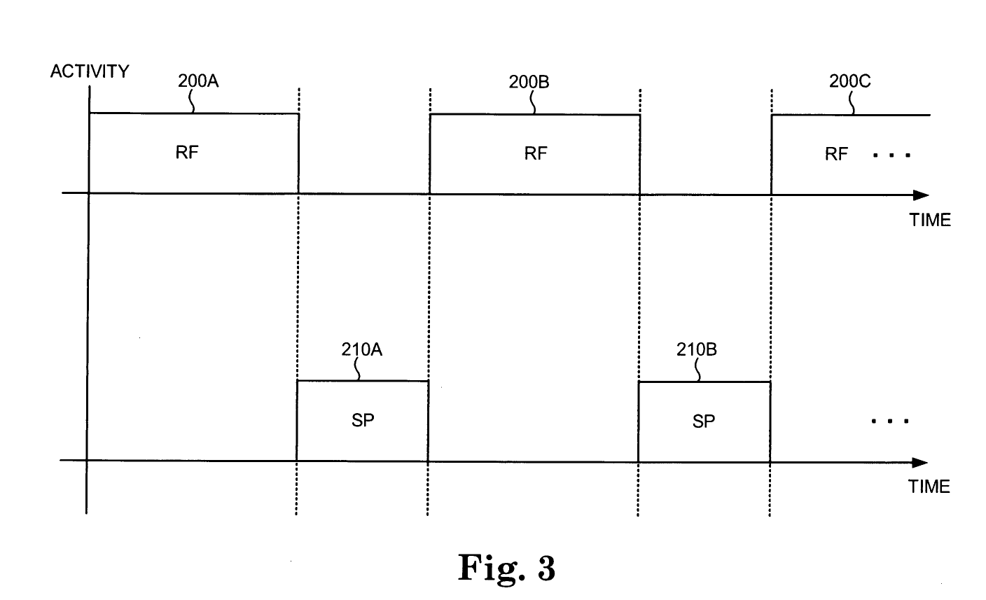

FIG. 3 is a graph illustrating one embodiment of a set of events in mobile communication system 100. Broadly speaking, two alternate events take place in system 100: RF reception or transmission, and signal processing. Put another way, the system arranges in time the RF reception or transmission activities of RF circuitry 120 and the digital activities of digital circuitry 130 so as to avoid or reduce interference between RF circuitry 120 and digital circuitry 130.

The methods and systems according to the invention may be applied in a variety of flexible ways and in a multitude of communication systems, as persons of ordinary skill in the art who have the benefit of the description of the invention understand. Generally, one may employ the novel concepts according to the present invention in time-division-multiplexed (TDM) communication systems. Time-division multiple access (TDMA) systems are an example of TDM communication systems. (GSM and GPRS systems constitute other TDM communication systems.) Furthermore, one may readily configure communication apparatuses according to the invention to operate according to a variety of communication protocols, channels, and frequency bands (e.g., GSM, PCS, and DCS), as desired.

In particular, the systems and methods of the present invention may be implemented in conjunction with a time-domain isolation nature of the system or apparatus where the RF circuitry operates when the digital circuitry is inactive, and vice-versa as depicted in U.S. patent application Ser. No. 10/426,042, entitled “Highly Integrated Radio-Frequency Apparatus and Associated Methods” by Navdeep S. Sooch and G. Tyson Tuttle, filed on Apr. 29, 2003, which is herby incorporated in its entirety by reference for all purposes. As a consequence, neither the digital switching noise and associated harmonic content nor the noise associated with PLL 142 interfere significantly with the performance of RF circuitry 120, and vice-versa. To provide for the inclusion of RF circuitry 120 and digital circuitry 130 within the same or a single circuit partition 110 (e.g., IC or die), illustrative embodiments according to the invention may employ one or more storage devices to allow data to be stored between digital processing cycles and RF cycles in a time domain isolation system.

Referring to FIG. 3, communication systems or apparatus with time-domain isolation according to exemplary embodiments of the invention use a plurality of RF time-slots 200A, 200B, 200C, and so on. Such systems or apparatus also employ a plurality of signal-processing (SP) time-slots 210A, 210B, and so on (it will be understood that signal-processing may refer generally to any high speed activity of digital circuitry 130 in this context). During RF time-slots 200A-200C, the system or apparatus (e.g., the RF front-end in the system or apparatus such as RF circuitry 120) may receive RF signals (from a transmitter or transceiver) or transmit RF signals (to a receiver or transceiver), process the received signals, and store the results in one or more storage devices. Subsequently, during signal-processing time-slots 210A-210B, the system or apparatus (e.g., the signal-processing circuitry in the system or apparatus such as digital circuitry 130) may perform signal-processing tasks on the stored results. (Note, however, that the operation of the RF circuitry and the digital circuitry may overlap by some amount, as described below.)

Alternatively, during RF time-slots 200A-200C, the system or apparatus may transmit RF signals (to a receiver or transceiver). In this mode of operation, during signal-processing 210A-210B, the system or apparatus (e.g., the signal-processing circuitry in the system or apparatus such as digital circuitry 130) performs signal-processing tasks on input data (e.g., voice, data), and may store the results in one or more storage devices (not shown). Subsequently, during RF time-slots 200A-200C, the system or apparatus (e.g., the RF circuitry of the apparatus or system such as RF circuitry 120) may process transmit signals and perform RF operations (for example, up-conversion) on the stored results and transmit an RF signal.

Note that the signal-processing tasks performed during signal-processing time-slots 210A-210B may constitute the core signal-processing functions in an RF communication apparatus. Examples of such tasks include modulation, demodulation, coding, decoding, and the like.

Depending on the specific protocol, architecture, and circuitry used, the system or apparatus may receive and transmit simultaneously, as desired. More commonly, however, the system either transmits signals or receives signals during any of RF time-slots 200A-200C, or in bursts. For example, a GSM-compliant system or apparatus, such as a mobile telephone that complies with the GSM specifications, either receives or transmits RF signals in one or more bursts of activity during RF time-slots 200A-200C.

Note that RF time-slots 200A-200C may have the same or different durations, as desired. Generally, RF time-slots 200A-200C may have unequal lengths so as to accommodate a wide variety of circuitry, systems, protocols, and specifications, as desired. Each of RF time-slots 200A-200C may include several other time-slots or a frame, depending on the particular communication protocol or technique used. For example, in a GSM application, each RF time-slot may include a frame that in turn includes slots for various activities, such as RF reception, RF transmission, monitoring, idle slots, and the like, as described above.

Similarly, signal-processing time-slots 210A-210B may have similar or dissimilar durations, as desired. Generally speaking, the signal-processing time-slots may have unequal lengths so as to accommodate a broad array of signal-processing apparatus, circuitry, algorithms, and processing techniques. Each of signal-processing time-slots 210A-210B may include several other time-slots or time divisions, depending on the particular communication protocol and/or signal-processing techniques and the particular circuitry and technology used. For example, a signal-processing time-slot may include several time-slots, with a portion or particular circuitry active or processing signals during one or more of the time-slots.

Furthermore, one may perform the signal-processing tasks in a serial or multiplexed manner (e.g., by sharing hardware to perform a variety of tasks), in a parallel manner (e.g., by using dedicated hardware for each signal-processing task), or a combination of the two techniques, as desired. The choice of signal-processing hardware, firmware, and software depends on the design and performance specifications for a given desired implementation, as persons of ordinary skill in the art who have the benefit of the description of the invention understand.

To implement a communication system or apparatus with time-domain isolation according to the invention, one may activate, deactivate or switch between the RF circuitry and the digital (signal-processing) circuitry in a variety of ways, as persons of ordinary skill in the art who have the benefit of the description of the invention understand. For example, before a signal-processing time-slot commences, one may deactivate the RF circuitry by powering it down, disabling, or inhibiting its operation or its circuitry. When the signal-processing time-slot ends, one may activate or power up (and settle and calibrate, as appropriate) the RF circuitry to receive and/or transmit, as desired.

As another example, one may deactivate the signal-processing circuitry (e.g., before an RF time-slot commences) by disabling or inhibiting the clock signal or signals within the signal-processing circuitry. More specifically, by using static metal oxide semiconductor (MOS) circuitry, one may shut down the clock signal or signals within the signal-processing circuitry without losing the data present within that circuitry. Accordingly, the signal-processing circuitry can preserve the data within it while the RF circuitry operates. Once the RF circuitry has deactivated (e.g., an RF time-slot has ended), one may activate the signal-processing circuitry by asserting the clock signal or signals in order to commence or continue the processing of the data.

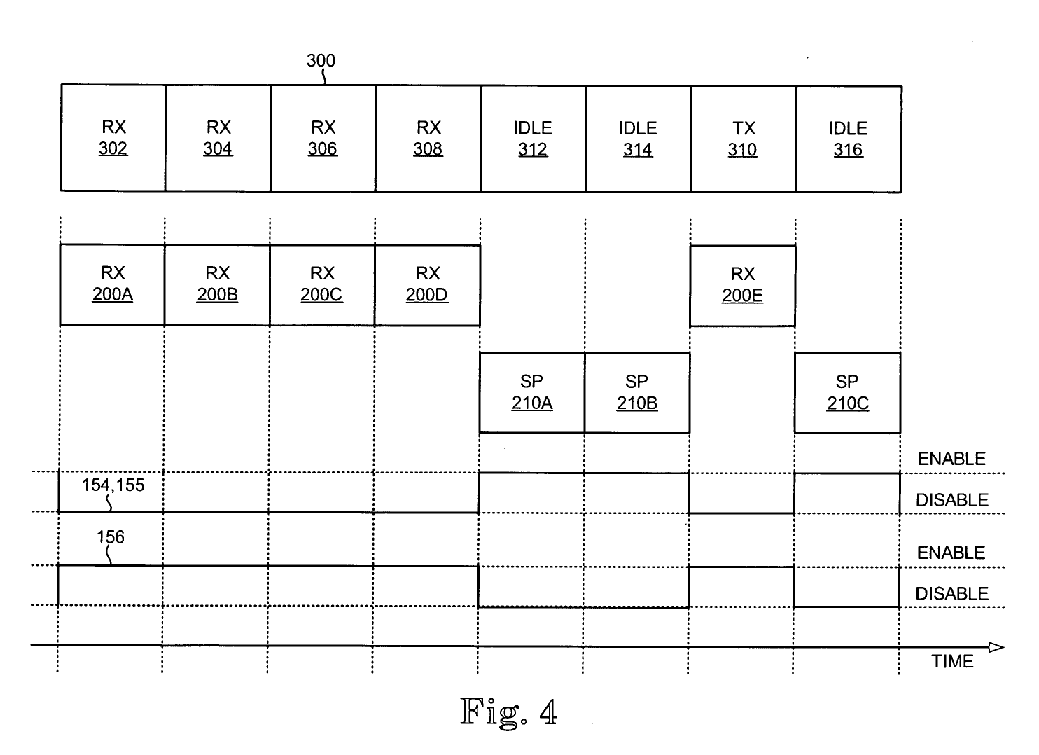

FIG. 4 is a graph illustrating one embodiment of time-domain isolation employed in a system, such as system 100, utilizing a GPRS class 12 application. FIG. 4 shows one example of a GPRS data frame 300 in a typical GPRS class 12 application. Frame 300 includes 8 slots which correspond to bursts of data, four receive slots 302, 304, 306, 308, one transmit slot 310 and three idle slots 312, 314, 316. It may be noted that the location of the various slots shown here are for exemplary purpose. The ideas incorporated herein will equally apply to any other arrangement of receive, transmit and idle slots (with monitoring functions) and that are compatible with any TDMA system including any GPRS systems up to GPRS Class 12, and any other future TDMA systems which may defined or utilized.

As shown in FIG. 4, RF time-slots 200A, 200B, 200C 200D and 200E may coincide with transmit slot 310 and receive slots 302, 304, 306, 308 of exemplary GPRS frame 300, respectively. Signal-processing time-slots 210A, 210B, and 210C take place during idle slots 312, 314, and 316, respectively. Thus, during RF time-slots 200A-200E, RF circuitry 120 of mobile device 230 may be active, while during signal-processing time-slots (210A, 210B, 210C) PLL 142 and digital circuitry 130 may be active.

At some point during the exemplary GPRS frame 200 of FIG. 4, the function of monitoring signal strength of base stations can occur. This monitoring function is an RF activity and, therefore, can be considered a form of an “RF time-slot.” This monitoring function can occur at any time during any of idle slots 312, 314, and 316 (e.g., during any one of those slots or overlapping one or more of those slots) or at any other time designated by the GPRS or other applicable standard. During the RF function of monitoring, digital signal processing by digital circuitry 130 is deactivated. Accordingly, PLL 142 is deactivated during the RF function of monitoring.

FIG. 4 also includes timing diagrams illustrating the operation of enable signals 154, 155, and 156 by control circuitry 144 with reference to the slots in frame 300. Control circuitry 144 comprises a real time event controller responsible for transitioning between time-slots 200A, 200B, 200C, 200D, 200E, 210A, 210B and 210C using enable signals 154 and 156. In one embodiment, the operation of RF circuitry 120 and PLL 142 are synchronized with time-slots 200A, 200B, 200C, 200D, 200E, 210A, 210B and 210C during operation of mobile communications system 100.

As shown in FIG. 4, during receive slots 200A, 200B, 200C and 200D, PLL 142 and digital circuitry 130 are inactive as indicated by control circuitry 144 providing enable signals 154 and 155 at a “disable” logic level. RF circuitry is active as indicated by control circuitry 144 providing enable signal 156 at a “enable” logic level. During these RF time-slots 200A, 200B, 200C, 200D, then, RF circuitry 120 listens for or receives incoming signals with a minimum of interference from digital circuitry 130 or PLL 142.

At the end of receive slot 200D, control circuitry 144 deactivates RF circuitry 120 by providing enable signal 156 at a “disable” logic level and activates PLL 142 and digital circuitry 130 providing enable signals 154 and 155 at a “enable” logic level. Thus, during signal-processing time-slots 210A and 210B, RF circuitry 120 is inactive and digital circuitry 130 is active and is driven by digital circuitry clock signal 152 from PLL 142.

At the end of signal-processing time-slot 210B, the reverse process occurs where control circuitry 144 activates RF circuitry 120 by providing enable signal 156 at the “enable” logic level and deactivates PLL 142 and digital circuitry 130 providing enable signals 154 and 155 at the “disable” logic level. Thus, during RF time-slot 200E, RF circuitry 120 is active and digital circuitry 130 and PLL 142 are inactive. As a result, RF circuitry 120 transmits with a minimum of interference from digital circuitry 130 or PLL 142 during RF time-slot 200E while the state of digital circuitry 130 is maintained.

At the conclusion of RF.time-slot 200E, control circuitry 144 once again inactivates RF circuitry 120 by providing enable signal 156 at the “disable” logic level and PLL 142 and digital circuitry 130 providing enable signals 154 and 155 at the “enable” logic level. During signal-processing time-slot 210C, RF circuitry 120 is inactive and digital circuitry 130 is active and is driven by digital circuitry clock signal 152 from PLL 142. Similarly, at the end of signal processing time-slot 210C the reverse process occurs again where control circuitry 144 activates RF circuitry 120 by providing enable signal 156 at the “enable” logic level and deactivates PLL 142 and digital circuitry 130 providing enable signals 154 and 155 at the “disable” logic level.

It will be apparent to those of skill in the art, that when a monitoring signal strength function occurs during idle slots 312, 314 or 316 in FIG. 4, similar switching activities can occur if desired. Signal processing can be halted by disabling PLL 142 for the duration of the monitoring function.

It will also be apparent to those of skill in the art after reading this disclosure that the timing of events may be altered according to any number of criteria, including the hardware utilized in conjunction with mobile communication system 100.

In other embodiments, the timing of switching between RF circuitry 120 and PLL 142/digital circuitry 120 may be designed to give RF circuitry 120 time to settle before it is used for transmitting or receiving.

FIG. 5 is a block diagram illustrating one embodiment of a mobile communications device 500 that includes mobile communications system 100 as shown in FIG. 1. Mobile communications device 500 may be any type of portable communications device such as a mobile or cellular telephone, a personal digital assistant (PDA), and an audio and/or video player (e.g., an MP3 or DVD player). Mobile communications device 500 includes mobile communications system 100, a input/output system 502, a power supply 504, and an antenna 506.

Input/output system 502 receives information from a user and provides the information to mobile communications system 100. Input/output system 502 also receives information from mobile communications system 100 and provides the information to a user. The information may include voice and/or data communications. Input/output system 502 includes any number and types of input and/or output devices to allow a user provide information to and receive information from mobile communications device 500. Examples of input and output devices include a microphone, a speaker, a keypad, a pointing or selecting device, and a display device.

Power supply 504 provides power to mobile communications system 100, input/output system 502, and antenna 506. Power supply 504 includes any suitable portable or non-portable power supply such as a battery.

Mobile communications system 100 communicates with one or more base stations 510 or other remotely located hosts in radio frequencies using antenna 506. Mobile communications system 100 transmits information to one or more base stations 510 or other remotely located hosts in radio frequencies using antenna 506 as indicated by a signal 520. Mobile communications system 100 receives information from a base station 510 in radio frequencies using antenna 506 as indicated by a signal 530. In other embodiments, mobile communications system 100 communicates with base stations 510 using other frequency spectra.

In the above embodiments, one may use a variety of circuit and process technologies and materials to implement communication apparatus according to the invention. Examples of such technologies include metal oxide semiconductor (MOS), p-type MOS (PMOS), n-type MOS (NMOS), complementary MOS (CMOS), silicon-germanium (SiGe), gallium-arsenide (GaAs), silicon-on-insulator (SOI), bipolar junction transistors (BJTs), a combination of BJTs and CMOS (BiCMOS), etc. The choice of the technology, circuitry, and materials depends on such factors as design and performance goals and specifications, cost, targeted market segments, and the like, as persons of ordinary skill in the art who have the benefit of the description of the invention understand.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A mobile communications system comprising:
a phase-locked loop (PLL);
radio frequency (RF) circuitry; and
control circuitry configured to activate the PLL and the RF circuitry during a plurality of substantially mutually exclusive time intervals so that interference effects between the PLL and the RF circuitry tend to be reduced.

2. The mobile communications system of claim 1 wherein the control circuitry is configured to activate the PLL during one of the plurality of time intervals, and wherein the control circuitry is configured to deactivate the RF circuitry during the one of the plurality of time intervals.

3. The mobile communications system of claim 2 wherein the one of the plurality of time intervals substantially excludes an RF time slot.

4. The mobile communications system of claim 1 wherein the control circuitry is configured to deactivate the PLL during one of the plurality of time intervals, and wherein the control circuitry is configured to activate the RF circuitry during the one of the plurality of time intervals.

5. The mobile communications system of claim 4 wherein the one of the plurality of time intervals substantially includes an RF time slot.

6. The mobile communications system of claim 1 wherein the PLL and the RF circuitry reside within a single circuit partition.

7. The mobile communications system of claim 1 further comprising:
digital circuitry configured to receive a first clock signal from the PLL;
wherein the control circuitry is configured to activate the PLL during one of the plurality of time intervals to cause the PLL to provide the first clock signal to the digital circuitry, and wherein the control circuitry is configured to deactivate the RF circuitry during the one of the plurality of time intervals.

8. The mobile communications system of claim 5 further comprising:
clock circuitry configured to provide a second clock signal to the PLL;
wherein the PLL is configured to generate the first clock signal using the second clock signal.

9. The mobile communications system of claim 1 wherein the plurality of time intervals substantially coincide with a plurality of slots in a frame.

10. The mobile communications system of claim 1 wherein the system comprises a time division multiple access system.

11. A method performed by a system that includes radio frequency (RF) circuitry, the method comprising:
activating the RF circuitry during a first time interval; and
deactivating a phase-locked loop (PLL), associated with digital circuitry, during the first time interval.

12. The method of claim 11 further comprising:
deactivating the RF circuitry during a second time interval that is subsequent to the first time interval; and
activating the PLL during the second time interval to cause a first clock signal to be provided to the digital circuitry.

13. The method of claim 11 wherein the first time interval and the second time interval substantially coincide with a plurality of slots in a frame.

14. The method of claim 13 further comprising:
deactivating the digital circuitry during the first time interval; and
activating the digital circuitry during the second time interval.

15. The method of claim 13 further comprising:
providing a second clock signal to the PLL; and
generating the first clock signal with the second clock signal using the PLL.

16. The method of claim 11 wherein the first time interval substantially includes an RF time slot, and wherein the second time interval substantially includes a signal processing time slot.

17. The method of claim 11 wherein the PLL and the RF circuitry comprise a single circuit partition.

18. The method of claim 11 wherein the system comprises a time division multiple access system.

19. The method of claim 11 further comprising:
transmitting information using the RF circuitry during the first time interval.

20. The method of claim 11 further comprising:
receiving information using the RF circuitry during the first time interval.

21. A communications device comprising:
an antenna;
a mobile communications system including radio frequency (RF) circuitry and a phase-locked loop (PLL) and configured to communicate with a remote host using the antenna; and
an input/output system configured to communicate with the mobile communications system;
wherein the mobile communications system is configured to activate the RF circuitry during a first time interval, and wherein the mobile communications system is configured to deactivate the PLL during the first time interval.

22. The communications device of claim 21 wherein the mobile communications system is configured to deactivate the RF circuitry during a second time interval that is subsequent to the first time interval, and wherein the mobile communications system is configured to activate the PLL to generate a first clock signal using a second clock signal during the second time interval.

23. The communications device of claim 21 wherein the mobile communications system comprises digital circuitry configured to receive a clock signal from the PLL, and wherein the mobile communications system is configured to deactivate the digital circuitry during the first time interval.

24. The communications device of claim 21 wherein the mobile communications system comprises a time division multiple access system.

25. A system comprising:
means for activating radio frequency (RF) circuitry during a first time interval; and
means for deactivating a phase-locked loop (PLL) associated with digital circuitry during the first time interval.

26. The system of claim 25 further comprising:
means for deactivating the RF circuitry during a second time interval that is subsequent to the first time interval; and
means for activating the PLL during the second time interval to cause a first clock signal to be provided to the digital circuitry.
